(19) United States
(12) Patent Application Publication
(10) Pub. No.: US 2009/0106935 A1
(43) Pub. Date: Apr. 30, 2009

(54) HINGE WITH AN ELEVATING FUNCTION FOR A NOTEBOOK COMPUTER EXTENSION PAD

(76) Inventors: Cheng-Lung Tsai, Shulin City (TW); Chih-Kuang Chuan, Shulin City (TW)

Correspondence Address: RABIN & Berdo, PC, 1101 14TH STREET, NW, SUITE 500, WASHINGTON, DC, 20005, US

(21) Appl. No.: 11/930,632

(22) Filed: Oct. 31, 2007

(51) Int. Cl. H05K 7/16

(52) U.S. Cl. 16/223

(57) ABSTRACT

A hinge with an elevating function is mounted between a top panel and a bottom panel of an expansion pad and has a lower pivot bracket assembly, a pivoting arm assembly, an upper pivot bracket assembly and a top pivoting assembly. The lower pivot bracket assembly is mounted securely on the bottom panel. The pivoting arm assembly has an upper end and a lower end. The lower end of the pivoting arm assembly is mounted pivotally on the lower pivot bracket assembly. The upper pivot bracket assembly is mounted pivotally on the upper end of the pivoting arm assembly. The top pivoting assembly is attached securely to the top panel and is mounted pivotally on the upper pivot bracket assembly to allow the top panel to be moved up and down and to be pivoted relative to the bottom panel. Consequently, the operating height and angle are adjustable.

### BACKGROUND OF THE INVENTION

1. Field of the Invention

The present invention relates to a hinge, and more particularly to a hinge mounted in a notebook computer extension pad to elevate and pivot the extension pad to adjust the operating height and angle of the notebook computer.

2. Description of the Prior Arts

A conventional extension pad for a notebook computer is mounted below the notebook computer and has a thickness to elevate the notebook computer a specific height. However, the height is a function of the thickness of the extension pad and is not adjustable. Additionally, the extension pad can only be parallel to the surface on which it is placed so the notebook computer's angle cannot be adjusted to accommodate different people or use in different situations.

To overcome the shortcomings, the present invention provides a hinge with an elevating function for a notebook computer extension pad to mitigate or obviate the aforementioned problems.

### SUMMARY OF THE INVENTION

The primary objective of the present invention is to provide a hinge mounted in a notebook computer extension pad to elevate and pivot a notebook computer mounted on the extension pad to a comfortable operating angle.

The hinge with an elevating function for a notebook computer extension pad in accordance with the present invention is mounted between a top panel and a bottom panel of an expansion pad and has a lower pivot bracket assembly, a pivoting arm assembly, an upper pivot bracket assembly and a top pivoting assembly. The lower pivot bracket assembly is mounted securely on the bottom panel. The pivoting arm assembly has an upper end and a lower end. The lower end of the pivoting arm assembly is mounted pivotally on the lower pivot bracket assembly. The upper pivot bracket assembly is mounted pivotally on the upper end of the pivoting arm assembly. The top pivoting assembly is attached securely to the top panel and is mounted pivotally on the upper pivot bracket assembly to allow the top panel to be moved up and down and to be pivoted relative to the bottom panel. Consequently, the operating height and angle of the extension pad are adjustable.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a hinge with an elevating function for a notebook extension pad in accordance with the present invention mounted between a bottom panel and a top panel of an extension pad;

FIG. 2 is a perspective view of the hinge in FIG. 1;

FIG. 3 is an exploded perspective view of major components of the hinge in FIG. 1;

FIG. 4 is an enlarged exploded perspective view of a connection between a lower pivot bracket assembly and a pivoting arm assembly of the hinge in FIG. 1;

FIG. 5 is an enlarged exploded perspective view of a connection between a pivoting arm assembly and an upper pivot bracket assembly of the hinge in FIG. 1;

FIG. 6 is an enlarged exploded perspective view of a top pivoting assembly mounted on the upper pivot bracket assembly of the hinge in FIG. 1 connected to the pivoting arm assembly;

FIG. 7 is an operational side view of the hinge in FIG. 1 with the hinge extended;

FIG. 8 is an operational side view of the hinge in FIG. 1 with the hinge closed; and

FIG. 9 is an operational side view of the hinge in FIG. 1 with the hinge extended and the top pivoting assembly pivoted relative to the lower pivot bracket assembly.

### DETAILED DESCRIPTION OF THE PREFERRED EMBODIMENTS

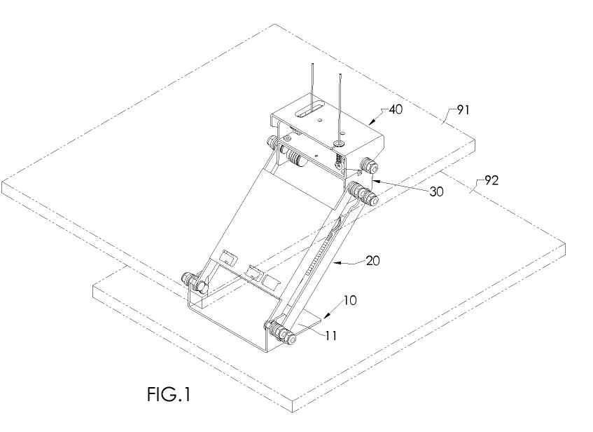

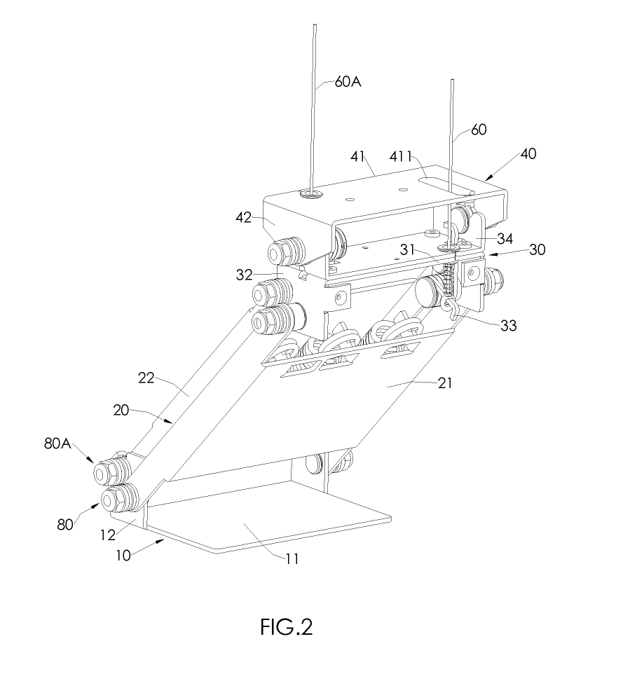

With reference to FIGS. 1 and 2, a hinge with an elevating function for a notebook computer extension pad in accordance with the present invention is mounted in an extension pad, comprises a lower pivot bracket assembly (10), a pivoting arm assembly (20), an upper pivot bracket assembly (30) and a top pivoting assembly (40) and may have at least one release wire (60, 60A).

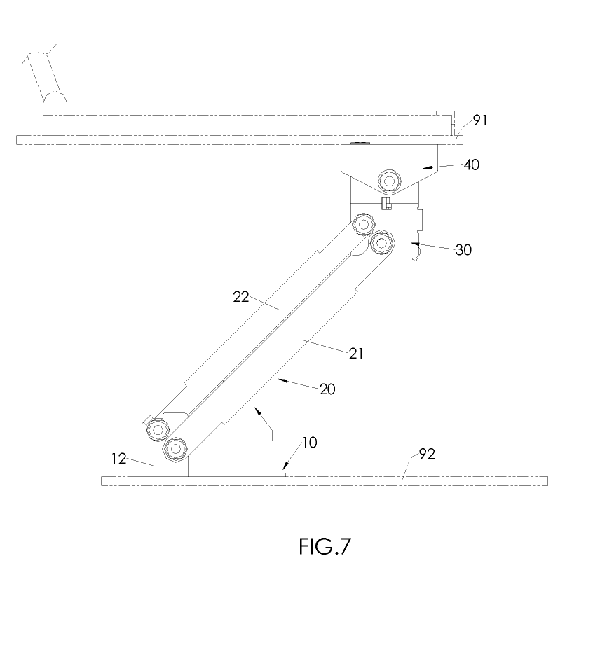

With further reference to FIG. 7, the extension pad is mounted below the notebook computer and has a top panel (91) and a bottom panel (92). The top panel (91) is flat and is mounted below the notebook. The bottom panel (92) is mounted below the top panel (91).

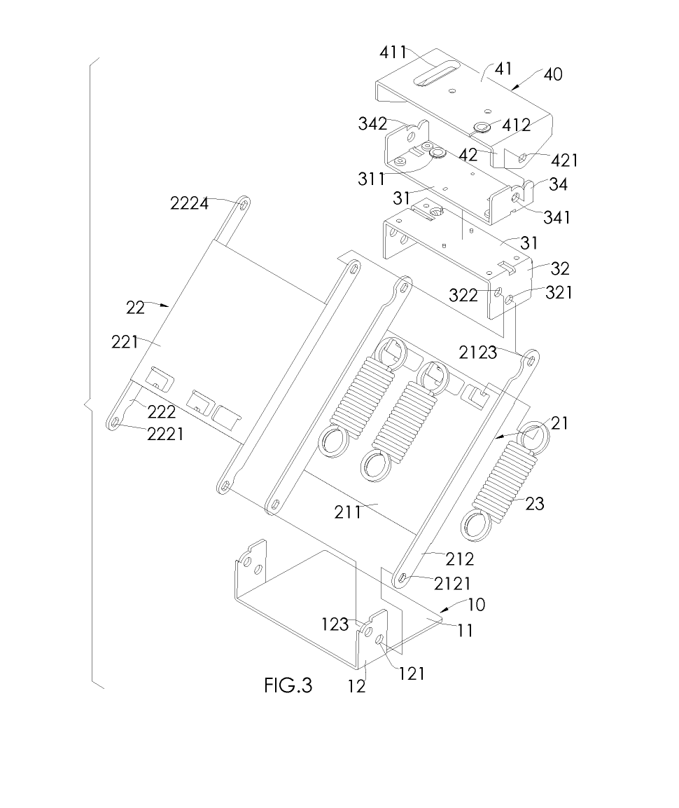

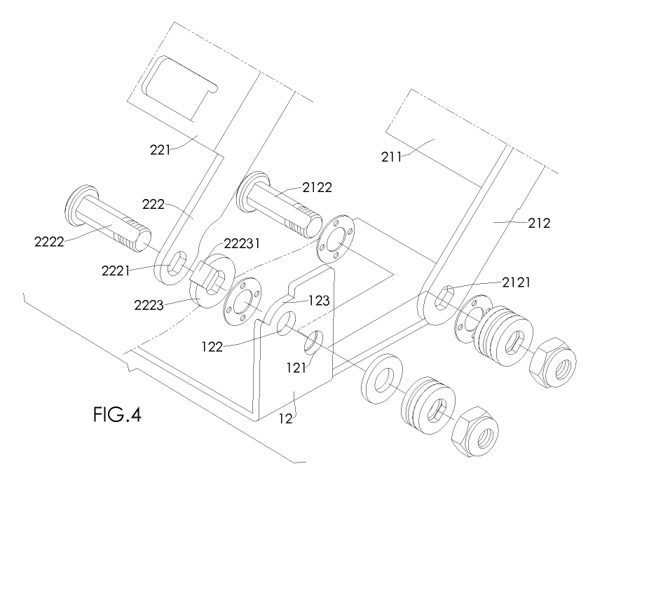

With reference to FIGS. 3 and 4, the lower pivot bracket assembly (10) is mounted securely on the bottom panel (92) and may be implemented with a base (11) and two wings (12).

The base (11) is mounted securely on the bottom panel (92) and has a rear edge and two sides.

The wings (12) are formed respectively on and protrude up from the sides of the base (11) adjacent to the rear edge, and each wing (12) has a top edge, a front edge, a rear edge, an upper pivot hole (122), a lower pivot hole (121) and a limit notch (123).

The upper pivot hole (122) is formed through the wing (12) near the rear edge and the top edge.

The lower pivot hole (121) is formed through the wing (12) near the front edge below the upper pivot hole (122).

The limit notch (123) is formed in the rear edge and the top edge of the wing (12) near and concentrically with the upper pivot hole (122) and has a curved edge and two stops. The curved edge has two ends. The stops are formed radially respectively at the ends of the curved edge.

The pivoting arm assembly (20) has an upper end and a lower end and may have a front pivoting arm (21), a rear pivoting arm (22) and at least one lifting spring (23).

The lower end of the pivoting arm assembly (20) is connected pivotally to the lower pivot bracket assembly (10).

The front pivoting arm (21) is H-shaped, is connected pivotally to the wings (12) and has a body (211) and two connecting bars (212).

The body (211) is a flat sheet and has two side edges, a front end and a rear end.

The connecting bars (212) of the front pivoting arm (21) are formed respectively on and protrude up from the side edges of the body (211) parallel to each other, protrude beyond the front and rear ends and are connected pivotally respectively to the wings (12). Each connecting bar (212) has a lower end, an upper end, a middle, a lower keyed hole (2121), a keyed connector (2122) and an upper keyed hole (2123).

The lower ends of the connecting bars (212) are connected pivotally respectively to the wings (12).

The lower keyed holes (2121) are formed respectively through the connecting bars (212) near the lower ends and align respectively with the lower pivot holes (121) of the wings (12).

The keyed connectors (2122) are mounted securely respectively in the lower keyed holes (2121) and protrude pivotally respectively through the lower pivot holes (121) of the wings (12) to connect the connecting bars (212) pivotally respectively to the wings (12).

The upper keyed holes (2123) are formed respectively through the connecting bars (212) near the upper ends.

The rear pivoting arm (22) is H-shaped, is connected pivotally to the wings (12) parallel to the front pivoting arm (21) and has a body (221) and two connecting bars (222).

The body (221) is a flat sheet and has two side edges, a front end and a rear end.

The connecting bars (222) of the rear pivoting arm (22) are formed respectively on and protrude up from the side edges of the body (221) parallel to each other, protrude beyond the front and rear ends and are connected pivotally respectively to the wings (12). Each connecting bar (222) has a lower end, an upper end, a middle, a lower keyed hole (2221), a keyed connector (2222), a limiting ring (2223) and an upper keyed hole (2224).

The lower ends of the connecting bars (222) are connected pivotally respectively to the wings (12).

The lower keyed holes (2221) are formed respectively through the connecting bars (222) of the rear pivoting arm (22) near the lower ends and align respectively with the upper pivot holes (122) of the wings (12).

The keyed connectors (2222) are mounted securely respectively in the lower keyed holes (2221) of the connecting bars (222) of the rear pivoting arm (22) and protrude pivotally respectively through the upper pivot holes (122) of the wings (12) to connect the connecting bar (222) of the rear pivoting arm (22) pivotally respectively to the wings (12).

The limiting rings (2223) are mounted securely respectively around the keyed connectors (2222) of the connecting bars (222) of the rear pivoting arm (22) adjacent respectively to the limit notches (123), and each limiting ring (2223) has a limiting protrusion (22231). The limiting protrusion (22231) is formed on the limiting ring (2223), protrudes slidably into the corresponding limit notch (123) and selectively abuts the stops of the limit notch (123) to limit how much the pivoting arm assembly (20) will pivot.

The upper keyed holes (2224) are formed respectively through the connecting bars (222) of the rear pivoting arm (22) near the upper ends.

The at least one lifting spring (23) is mounted between the front end of the body (211) of the front pivoting arm (21) and the rear end of the body (221) of the rear pivoting arm (22), is parallel to adjacent lifting springs (23) and applies a torque to the front and rear pivoting arms (21, 22) to pivot the pivoting arm assembly (20) at wings (12) up from the base (11) of the lower pivot bracket assembly (10).

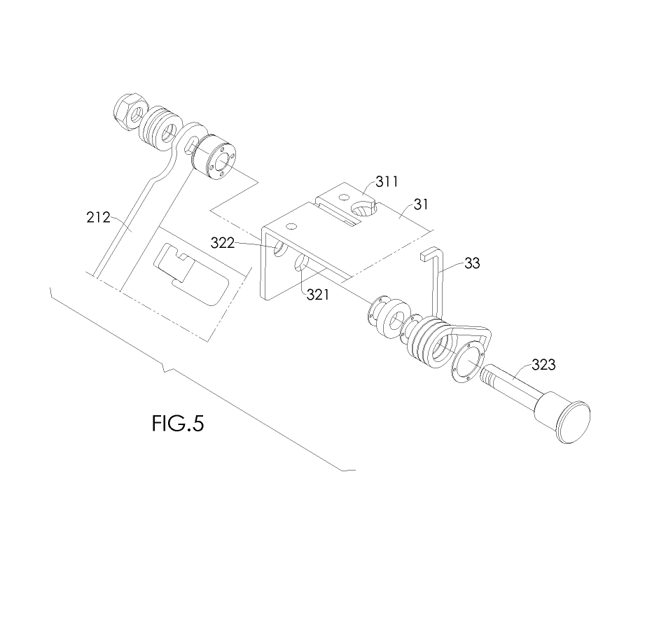

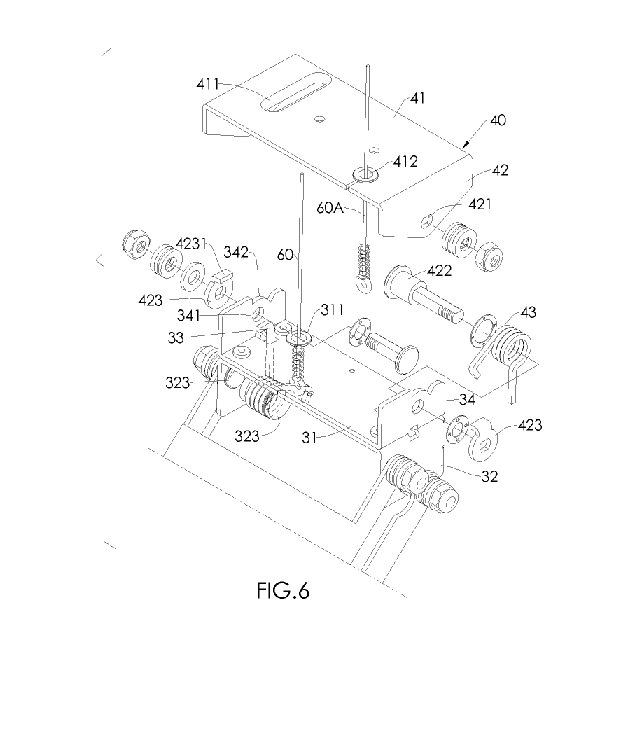

With further reference to FIGS. 5 and 6, the upper pivot bracket assembly (30) is mounted pivotally on the upper end of the pivoting arm assembly (20) and may be implemented with a base (31), two lower wings (32), a torsion spring (33) and two upper wings (34).

The base (31) is parallel to the base (11) of the lower pivot bracket assembly (10), may be formed with two adjacent panels and has a rear edge, two sides and a wire hole (311).

The wire hole (311) is formed through the base (31) near the rear edge and one of the sides.

The lower wings (32) are formed on and protrude down respectively from the sides of the base (31) and are mounted pivotally respectively on the upper ends of the connecting bars (212, 222) of the front and rear pivoting arms (21, 22). Each lower wing (32) has a bottom edge, a rear edge, an upper pivot hole (322), a lower pivot hole (321) and two keyed connectors (323).

The upper pivot hole (322) is formed through the lower wing (32) near the rear edge and the base (31), corresponds to the upper pivot hole (122) of the corresponding wing (12) of the lower pivot bracket assembly (10) and aligns with the upper keyed hole (2224) of the corresponding connecting bar (222) of the rear pivoting arm (22).

The lower pivot hole (321) is formed through the lower wing (32) forward of the upper pivot hole (322) near the bottom edge, corresponds to the lower pivot hole (121) of the corresponding wing (12) of the lower pivot bracket assembly (10) and aligns with the upper keyed hole (2123) of the corresponding connecting bar (212) of the front pivoting arm (21).

The keyed connectors (323) are mounted respectively through the upper and lower pivot holes (322, 321) and respectively through the upper keyed holes (2224, 2123) to connect the upper pivot bracket (32) pivotally to the front and rear pivoting arms (21, 22).

The torsion spring (33) is mounted around and squeezes the keyed connector (323) adjacent to the wire hole (311) to keep the pivoting arm assembly (20) from pivoting freely and has a stationary end and a free end. The stationary end of the torsion spring (33) protrudes tangentially from the torsion spring (33) and is connected to and held in place by the base (31) of the upper pivot bracket assembly (30). The free end of the torsion spring (33) protrudes tangentially from the torsion spring (33) such that pulling the free end up releases pressure on the keyed connector (323) and allows the pivoting arm assembly (20) to pivot freely.

The upper wings (34) are formed respectively on and protrude up respectively from the sides of the base (31). Each upper wing (34) has a top edge, a pivot hole (341) and a limit notch (342).

The pivot holes (341) are formed respectively through the upper wings (34) near the top edge.

The limit notches (342) are formed respectively in the top edges of the upper wings (34) respectively near and concentric with the pivot holes (341), and each limit notch (342) has a curved edge and two stops. The curved edge has two ends. The stops are formed radially respectively at the ends of the curved edge.

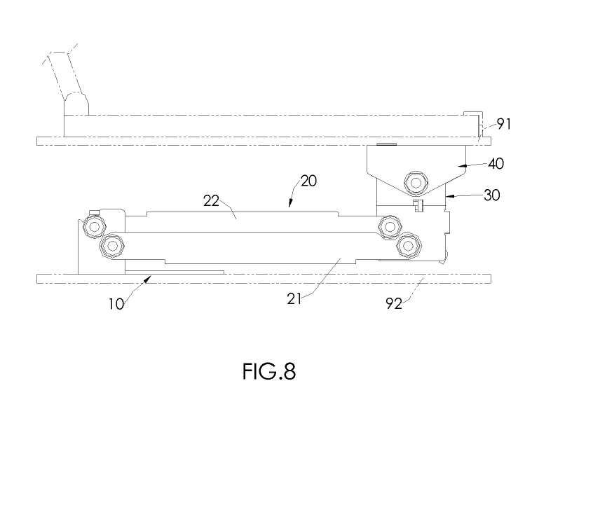

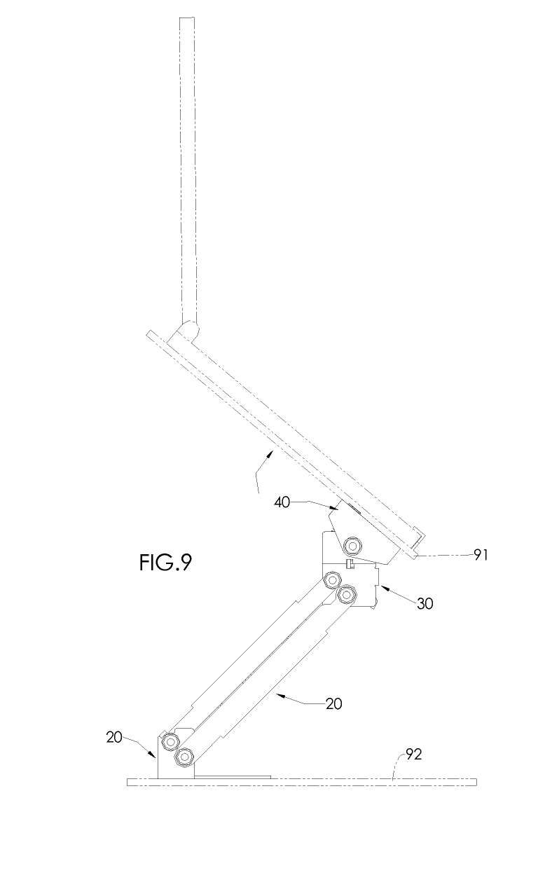

With further reference to FIGS. 8 and 9, the top pivoting assembly (40) is attached securely to the top panel (91), is mounted pivotally on the upper pivot bracket assembly (30), can be moved up and down to change position of the top panel (91) by pivoting the pivoting arm assembly (20), can be pivoted to tilt the top panel (91) and a device mounted on the top panel (91) and may be implemented with a base (41), two wings (42) and a torsion spring (43).

The base (41) is attached securely to the top panel (91) and has a front edge, a rear edge, two sides, an elongated through hole (411) and a wire hole (412).

The elongated through hole (411) is formed through the base (41) between the front and rear edges and aligns with the wire hole (311) in the base (31) of the upper pivot bracket assembly (30).

The wire hole (412) is formed through the base (41) near the rear edge and the side the side opposite to the elongated through hole (411).

The wings (42) are formed respectively on and protrude down respectively from the sides of the base (41), are mounted pivotally respectively on the upper wings (34) of the upper pivot bracket assembly (30) to allow the top panel (91) to pivot relative to the base (11) of the lower pivot bracket assembly (10), and each wing (42) has a bottom edge, a keyed hole (421), a keyed connector (422) and a limiting ring (423).

The keyed holes (421) of the wings (42) are formed respectively through the wings (42) near the bottom edge and align respectively with the pivot holes (341) of the upper wings (34) of the upper pivot bracket assembly (30).

The keyed connectors (422) are mounted securely respectively through the keyed holes (421) of the wings (42) and respectively through the pivot holes (341) of the upper wings (34) to mount the wings (42) pivotally on the upper wings (34) of the upper pivot bracket assembly (30).

The limiting rings (423) are mounted securely respectively around the keyed connectors (422) of the wings (42) adjacent respectively to the limit notches (342), and each limiting ring (423) has a limiting protrusion (4231). The top limiting protrusion (4231) is formed on the limiting ring (423), protrudes slidably into the corresponding limit notch (342) on the upper wing (34) of the upper pivot bracket assembly (30) and selectively abuts the stops of the limit notch (342) to limit how much the top pivoting assembly (40) will tilt.

The torsion spring (43) of the top pivoting assembly (40) is mounted around the keyed connector (422) of the top pivoting assembly (40) to keep the top pivoting assembly (40) from pivoting freely and has a stationary end and a free end. The stationary end of the torsion spring (43) protrudes tangentially from the torsion spring (43) and is attached to the base (31) of the upper pivot bracket assembly (30). The free end of the torsion spring (43) protrudes tangentially from the torsion spring (43) and pulling the free end up releases pressure on the keyed connector (422) of the top pivoting bracket (42) and allows the top pivoting assembly (40) to tilt freely.

The at least one release wire (60, 60A) may be an extension release wire (60), a tilt release wire (60A) or both and allows the hinge to extend or tilt easily when pulled.

The extension release wire (60) is attached to the free end of the torsion spring (33) of the pivoting arm assembly (30) and extends through the wire hole (311) of the base (31) of the pivoting arm assembly (30) and the elongated through hole (411) of the base (41) of the top pivoting assembly (40). Pulling the extension release wire (60) from outside of the hinge causes the torsion spring (33) to uncoil and release the keyed connector (323) so the pivoting arm assembly (20) will pivot freely and allow the hinge to easily extend or contract. Releasing the extension release wire (60) allows the torsion spring (33) to squeeze the keyed connector (323) and hold the pivoting arm assembly (20) in place.

The tilt release wire (60A) is attached to the free end of the torsion spring (43) of the top pivoting assembly (40) and extends through the wire hole (412) of the base (41) of the top pivoting assembly (40). Pulling the tilt release wire (60A) from outside of the hinge causes the torsion spring (433) to uncoil and release the keyed connector (422) so the top pivoting assembly (20) will pivot freely and allow the hinge to easily tilt.

Consequently, the hinge allows the top panel (91) to be moved up and down and pivoted relative to the bottom panel (92) such that a person can adjust the extension pad to a preferred height and angle needed to operate an electronic device mounted on the top panel (91).

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A hinge with an elevating function for a notebook computer extension pad comprising
a lower pivot bracket assembly;
a pivoting arm assembly having
an upper end; and
a lower end being connected pivotally to the lower pivot bracket assembly;
an upper pivot bracket assembly being mounted pivotally on the upper end of the pivoting arm assembly; and
a top pivoting assembly being mounted pivotally on the upper pivot bracket assembly.

2. The hinge as claimed in claim 1, wherein
the lower pivot bracket assembly has
a base having
a rear edge; and
two sides; and
two wings being formed respectively on and protruding up from the sides of the base adjacent to the rear edge, and each wing having
a top edge;
a front edge;
a rear edge;
an upper pivot hole being formed through the wing near the rear edge and the top edge of the wing; and
a lower pivot hole being formed through the wing near the front edge below the upper pivot hole;
the pivoting arm assembly further has
a front pivoting arm being H-shaped, being connected pivotally to the wings and having
a body being a flat sheet and having
two side edges;
a front end; and
a rear end; and
two connecting bars being formed respectively on and protruding up from the side edges of the body parallel to each other, protruding beyond the front and rear ends of the body and being connected pivotally respectively to the wings, and each connecting bar having
a lower end being connected pivotally to a corresponding one of the wings;
an upper end;
a middle;
a lower keyed hole being formed through the connecting bar near the lower end and aligning with the lower pivot hole of a corresponding one of the wings;
a keyed connector being mounted securely in the lower keyed hole and protruding respectively through the lower pivot hole of the wing; and
an upper keyed hole being formed through the connecting bar near the upper end; and
a rear pivoting arm being H-shaped, being connected pivotally to the wings parallel to the front pivoting arm and having
a body being a flat sheet and having
two side edges;
a front end; and
a rear end; and
two connecting bars being formed respectively on and protruding up from the side edges of the body parallel to each other, protruding beyond the front and rear ends of the body and being connected pivotally respectively to the wings, and each connecting bar of the rear pivoting arm having
a lower end being connected pivotally to a corresponding one of the wings;
an upper end;
a middle;
a lower keyed hole being formed through the connecting bar of the rear pivoting arm near the lower end and aligning with the upper pivot hole of a corresponding one of the wings;
a keyed connector being mounted securely in the lower keyed hole of the connecting bar of the rear pivoting arm and protruding through the upper pivot hole of a corresponding one of the wings; and
an upper keyed hole being formed through the connecting bar of the rear pivoting arm near the upper end; and
the upper pivot bracket assembly has
a base being parallel to the base of the lower pivot bracket assembly and having
a rear edge; and
two sides;
two lower wings being formed on and protruding down respectively from the sides of the base and being mounted pivotally respectively on the upper ends of the connecting bars of the front and rear pivoting arms, each lower wing having
a bottom edge;
a rear edge;
an upper pivot hole being formed through the lower wing near the rear edge and the base, corresponding to the upper pivot hole of one of the wings of the lower pivot bracket assembly and aligning with the upper keyed hole of a corresponding connecting bar of the rear pivoting arm;
a lower pivot hole being formed through the lower wing forward of the upper pivot hole near the bottom edge, corresponding to the lower pivot hole of the corresponding wing of the lower pivot bracket assembly and aligning with the upper keyed hole of the corresponding connecting bar of the front pivoting arm; and
two keyed connectors being mounted pivotally respectively through the upper and lower pivot holes of the lower wings and respectively through the upper keyed holes; and
two upper wings being formed respectively on and protruding up respectively from the sides of the base, and each upper wing having
a top edge; and
a pivot hole being formed through the upper wing near the top edge;
the top pivoting assembly has
a base having
a front edge;
a rear edge; and
two sides; and
two wings being formed respectively on and protruding down respectively from the sides of the base and being mounted pivotally respectively on the upper wings, and each wing having
a bottom edge;
a keyed hole being formed through the wing near the bottom edge and aligning with the pivot hole of a corresponding one of the upper wings of the upper pivot bracket assembly; and
a keyed connector being mounted securely through the keyed hole of the wing and through the pivot hole of the corresponding upper wing of the upper pivot bracket assembly.

3. The hinge as claimed in claim 2, wherein
the base of the upper pivot bracket assembly further has a wire hole being formed through the base near the rear edge and one of the sides;
the upper pivot bracket assembly further has a torsion spring being mounted around and squeezing one of the keyed connectors of the upper pivot bracket adjacent to the wire hole and having
a stationary end protruding tangentially from the torsion spring and being connected to and held in place by the base of the upper pivot bracket assembly; and
a free end protruding tangentially from the torsion spring;
the base of the top pivoting assembly further has
an elongated through hole being formed through the base between the front and rear edges and aligning with the wire hole of the base of the upper pivot bracket assembly; and
a wire hole being formed through the base near the rear edge and the side opposite to the elongated through hole;
the top pivoting assembly further has a torsion spring being mounted around one of the keyed connectors of the top pivoting assembly and having
a stationary end protruding tangentially from the torsion spring and being attached to the base of the upper pivot bracket assembly; and
a free end protruding tangentially from the torsion spring;
the hinge further comprises two release wires comprising
an extension release wire being attached to the free end of the torsion spring of the pivoting arm assembly and extending through the wire hole of the base of the pivoting arm assembly and the elongated through hole of the base of the top pivoting assembly; and
a tilt release wire being attached to the free end of the torsion spring of the top pivoting assembly and extending through the wire hole of the base of the top pivoting assembly.

4. The hinge as claimed in claim 3, wherein the pivoting arm assembly further has at least one lifting spring being mounted between the front end of the body of the front pivoting arm and the rear end of the body of the rear pivoting arm.

5. The hinge as claimed in claim 4, wherein
each wing of the lower pivot bracket assembly further has a limit notch being formed in the rear edge and the top edge of the wing near and concentrically with the upper pivot hole in the wing and having
a curved edge having two ends; and
two stops being formed radially respectively at the ends of the curved edge;
each connecting bar of the rear pivoting arm further has a limiting ring being mounted securely around the keyed connector of the connecting bar of the rear pivoting arm adjacent to a corresponding one of the limit notches, and having a limiting protrusion being formed on the limiting ring, protruding slidably into the corresponding limit notch and selectively abutting the stops of the corresponding limit notch;
each upper wing of the upper pivot bracket assembly further has a limit notch being formed in the top edge of the upper wing near and concentric with the pivot hole in the upper wing, and each limit notch having
a curved edge having two ends; and
two stops being formed radially respectively at the ends of the curved edge;
each wing of the top pivoting assembly further has a limiting ring being mounted securely around the keyed connector of the wing adjacent to a corresponding one of the limit notches in the upper wing, and having a limiting protrusion being formed on the limiting ring, protruding slidably into the corresponding limit notch and selectively abutting the stops of the corresponding limit notch.
